(19) United States
(12) Patent Application Publication
(10) Pub. No.: US 2022/0254683 A1
(43) Pub. Date: Aug. 11, 2022

(54) REMOVAL OF STRAY RUTHENIUM METAL NUCLEI FOR SELECTIVE RUTHENIUM METAL LAYER FORMATION

(71) Applicants: Tokyo Electron Limited, Tokyo (JP); The Regents of the University of Colorado, a body corporate, Denver, CO (US)

(72) Inventors: Omid Zandi, Austin, TX (US); Jacques Faguet, Austin, TX (US); David Zywotko, Boulder, CO (US); Steven M. George, Boulder, CO (US)

(21) Appl. No.: 17/573,946

(22) Filed: Jan. 12, 2022

Related U.S. Application Data
(60) Provisional application No. 63/146,494, filed on Feb. 5, 2021.

(51) Int. Cl. H01L 21/768; C23C 16/06; H01L 21/311

(52) U.S. Cl. CPC H01L 21/76865; H01L 21/76867; H01L 21/31116; C23C 16/06

(57) ABSTRACT

A method for removal of stray Ru metal nuclei for selective Ru metal layer formation includes depositing ruthenium (Ru) metal on a patterned substrate by vapor phase deposition, where a Ru metal layer is deposited on a surface of a metal layer and Ru metal nuclei are deposited on a surface of a dielectric layer. The method further includes removing the Ru metal nuclei by gas phase etching using an ozone (O₃) gas exposure that forms volatile ruthenium oxide species by oxidation of the Ru metal nuclei, and repeating the depositing and removing steps at least once to increase a thickness of the Ru metal layer, where the depositing is interrupted before the Ru metal nuclei reach a critical size that results in formation of non-volatile ruthenium oxide species and incomplete removal of the Ru metal nuclei during the gas phase etching.

### CROSS REFERENCE TO RELATED PATENTS AND APPLICATIONS

This application claims priority to and the benefit of the filing date of U.S. Provisional Patent Application No. 63/146,494, filed Feb. 5, 2021, which application is incorporated herein by reference in its entirety.

### FIELD OF THE INVENTION

The present invention relates to semiconductor processing and semiconductor devices, and more particularly, to a method for removal of stray ruthenium metal nuclei from non-growth surfaces for selective ruthenium metal layer formation.

### BACKGROUND OF THE INVENTION

Semiconductor devices contain filled recessed features such as trenches or vias that are formed in a dielectric material such as an interlayer dielectric (ILD). Selective metal filling of the recessed features is problematic due to finite metal deposition selectivity on a metal layer at the bottom of the recessed features relative to on the dielectric material. This makes it difficult to fully fill the recessed features with a metal in a bottom-up deposition process before the on-set of unwanted metal nuclei deposition on the field area (horizontal area) around the recessed features and on the sidewalls of the recessed features.

### SUMMARY OF THE INVENTION

A method is provided for removal of stray Ru metal nuclei for selective Ru metal layer formation. According to one embodiment, a method of forming a semiconductor device includes providing a patterned substrate containing a dielectric layer and a metal layer, and depositing ruthenium (Ru) metal on the patterned substrate by vapor phase deposition, where a Ru metal layer is deposited on a surface of the metal layer and Ru metal nuclei are deposited on a surface of the dielectric layer. The method further includes removing the Ru metal nuclei by gas phase etching using an ozone (O₃) gas exposure that forms volatile ruthenium oxide species by oxidation of the Ru metal nuclei. Thereafter, the method further includes repeating the depositing and removing steps at least once to increase a thickness of the Ru metal layer. The depositing of the Ru metal is interrupted before the Ru metal nuclei reach a critical size that results in formation of non-volatile ruthenium oxide species and incomplete removal of the Ru metal nuclei during the gas phase etching.

According to one embodiment, the method includes providing a patterned substrate containing a dielectric layer and a metal layer, and depositing ruthenium (Ru) metal on the patterned substrate by vapor phase deposition, where a Ru metal layer is deposited on a surface of the metal layer and Ru metal nuclei are deposited on a surface of the dielectric layer. The method further includes removing a portion of the Ru metal nuclei by gas phase etching using an O₃ gas exposure that forms volatile ruthenium oxide species by oxidation of the Ru metal nuclei, exposing the patterned substrate to a reducing gas containing H₂ gas that converts any non-volatile ruthenium oxide species formed during the O₃ gas exposure back to metallic Ru, and repeating the depositing, removing, and exposing steps at least once to increase a thickness of the Ru metal layer. According to one embodiment, the removing and exposing steps are repeated at least once to fully remove the Ru metal nuclei before the depositing step is repeated.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1D schematically show through schematic cross-sectional views a method for selective Ru metal layer formation in a recessed feature according to an embodiment of the invention;

FIG. 2 shows Ru metal nuclei size as a function of number of ozone gas exposures during gas phase etching according to an embodiment of the invention;

FIG. 3 shows thickness of Ru metal deposited on a metal layer and on a dielectric layer as a function of time according to an embodiment of the invention;

FIGS. 4A-4D schematically show etching of Ru metal nuclei using sequential O₃ gas and H₂ gas exposures according to an embodiment of the invention; and

FIG. 5 is a gas flow diagram for selectively forming a Ru metal layer on a metal layer.

### DETAILED DESCRIPTION OF SEVERAL EMBODIMENTS

Embodiments of the invention provide a method for selectively forming a low-resistivity Ru metal layer on a metal layer relative to a dielectric layer on a patterned substrate. According to one embodiment, exposed surfaces of the dielectric layer and the metal layer are in the same horizontal plane, for example after a planarization process. According to another embodiment, a recessed feature is formed in the dielectric layer and the metal layer is exposed in the recessed feature. The recessed feature can include a trench having a first width, and a via containing the metal layer and having a second width that is less than the first width. However, the method is not limited to those structures and may be applied to simpler and more complex structures found in manufacturing of semiconductor devices.

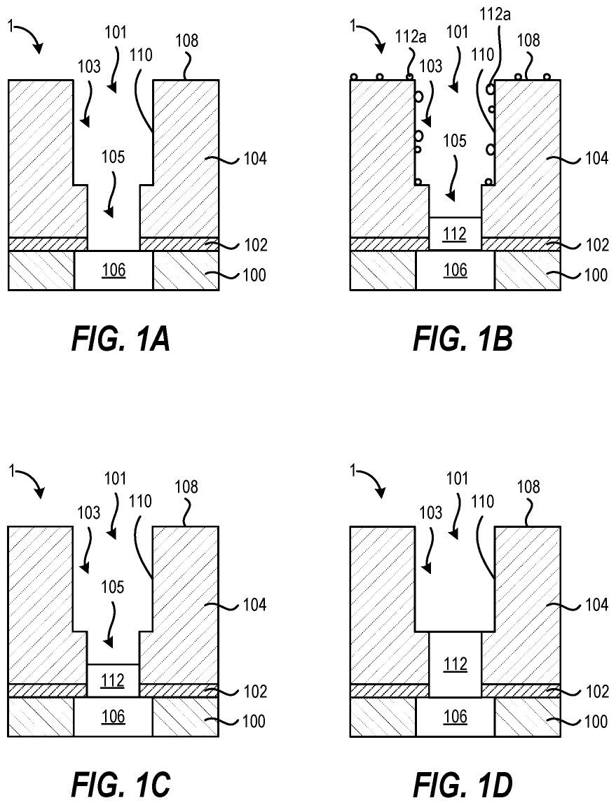

FIGS. 1A-1D schematically show through schematic cross-sectional views a method for selective Ru metal layer formation in a recessed feature according to an embodiment of the invention. A process chamber may be used that contains a substrate holder for supporting the patterned substrate 1 and maintaining the patterned substrate 1 at a desired substrate temperature during the processing at sub-atmospheric pressure. The process chamber may be configured for vapor phase deposition of Ru metal on the patterned substrate 1 and optionally further configured for gas phase etching of the Ru metal on the patterned substrate 1 using ozone (O₃) gas. According to one embodiment, the process chamber may further be configured for introducing O₃ gas, H₂ gas, or a H₂/O₃ gas mixture.

As schematically shown in FIG. 1A, the method includes providing the patterned substrate 1 in the process chamber, where the patterned substrate 1 contains a dielectric layer 104, a metal layer 106, an etch stop layer 102, and a bottom dielectric layer 100 surrounding the metal layer 106. A recessed feature 101 containing a trench 103 and a via 105 is etched through the dielectric layer 104 and the etch stop layer 102, thereby exposing a top surface of the metal layer 106 in the recessed feature 101. In one example, the metal layer can be a M1 layer in a semiconductor device. The metal layer 106 can, for example, be selected from the group consisting of Cu metal, Ru metal, Co metal, W metal, and combinations thereof. The dielectric layer 104 has exposed surfaces that include a field area 108 around the top of the recessed feature 101 and a sidewall 110 in the recessed feature 101.

According to one embodiment, the etch stop layer 102 and the dielectric layer 104 contain SiO₂, a low dielectric constant (low-k) material such as fluorinated silicon glass (FSG), carbon doped oxide, a polymer, a SiCOH-containing low-k material, a non-porous low-k material, a porous low-k material, a CVD low-k material, a spin-on dielectric (SOD) low-k material, or any other suitable dielectric material, including a high dielectric constant (high-k) material. In some examples, a width (critical dimension (CD)) of the via 105 in the recessed feature 101 can be between about 10 nm and about 100 nm, between about 10 nm and about 15 nm, between about 20 nm and about 90, or between about 40 nm and about 80 nm. In some examples, the depth of the via 105 can between bout 40 nm and about 200 nm, between about 50 nm and about 150, or between about 50 nm and about 150 nm. Further, in some examples, a width of the trench 103 can be between about 20 nm and about 200 nm, and a depth of the trench 103 can be between about 50 nm and about 300 nm.

The method further includes depositing Ru metal on the patterned substrate 1 by vapor phase deposition. According to some embodiments of the invention, the Ru metal may be deposited by chemical vapor phase deposition (CVD) or atomic layer deposition (ALD). Examples of volatile Ru precursors that may be used include triruthenium dodecacarbonyl (Ru₃(CO)₁₂), (2,4-dimethylpentadienyl) (ethylcyclopentadienyl) ruthenium (Ru(DMPD)(EtCp)), bis(2,4-dimethylpentadienyl) ruthenium (Ru(DMPD)₂), 4-dimethylpentadienyl) (methylcyclopentadienyl) ruthenium (Ru(DMPD)(MeCp)), and bis(ethylcyclopentadienyl) ruthenium (Ru(EtCp)₂), as well as combinations of these and other Ru precursors. In one example, Ru metal may be deposited by CVD using a Ru₃(CO)₁₂ precursor in a CO carrier gas.

As depicted in FIG. 1B, the Ru metal is deposited on the patterned substrate 1 as a Ru metal layer 112 on the metal layer 106 in the via 105 and as Ru metal nuclei 112a on the dielectric layer 104, including on the field area 108 and on the sidewall 110 of the dielectric layer 104. The smaller amount of Ru metal deposited on the dielectric layer 104 than on the metal layer 106 is due to a longer incubation time for Ru metal deposition on the dielectric layer 104 than on the metal layer 106. According to one embodiment, the Ru metal layer 112 is a continuous layer and the Ru metal nuclei 112a form a non-continuous layer with gaps that expose the underlying dielectric layer 104.

The method further includes interrupting the deposition of the Ru metal and, thereafter, removing the unwanted Ru metal nuclei 112a from the dielectric layer 104 by gas phase etching using an ozone (O₃) gas exposure. This is schematically shown in FIG. 1C, where the Ru metal layer 112 is selectively formed on the metal layer 106 following the removal of the Ru metal nuclei 112a. In one example, O₂ gas may be flowed through a remote ozone generator that forms an O₃/O₂ mixture that contains about 10% O₃. Thereafter the O₃/O₂ mixture is flowed into the process chamber containing the patterned substrate 1. The exposure to the O₃ gas thermally oxidizes the Ru metal nuclei 112a to form volatile ruthenium oxide species (including RuO_{4(g)}) that desorb from the patterned substrate 1, thereby removing the Ru metal nuclei 112a. The O₃ gas exposure oxidizes the Ru metal nuclei 112a at a faster than the Ru metal layer 112, thereby enabling efficient removal of the Ru metal nuclei 112a from the dielectric layer 104, with only a small loss of the Ru metal layer 112. The oxidation reaction is thermodynamically favorable and kinetically faster on the Ru metal nuclei 112a than on the Ru metal layer 112 due to the higher surface area of the Ru metal nuclei 112a. The removal of the Ru metal nuclei 112a linearly scales with the gas pressure of O₃ (P(O₃)). In one example, P(O₃) can be about 2 Ton, or less. In one example, the patterned substrate 1 may be maintained at a temperature of about 180° C. during the O₃ gas exposure.

The sequential steps of depositing the Ru metal and removing the Ru metal nuclei 112a may be performed at the same or substantially the same substrate temperature (e.g., ˜180° C.) in a single process chamber. This allows for fast and effective processing of the patterned substrate 1 with high substrate throughput. Further, performing the sequential steps in a single process chamber can reduce substrate contamination and prevent air exposure.

The sequential steps of depositing the Ru metal and removing the Ru metal nuclei 112a may be repeated at least once to increase a thickness of the Ru metal layer 112 on the metal layer 106 in the recessed feature 101, until a desired thickness of the Ru metal layer 112 is achieved. In one example, shown in FIG. 1D, the sequential steps may be repeated until the via 105 is fully filled with the Ru metal layer 112.

Referring back to FIG. 1B, according to one embodiment, each time the Ru metal deposition is performed, the depositing is interrupted by stopping the vapor phase exposure before the Ru metal nuclei 112a reach a critical size. According to one embodiment, this critical size is less than 4 nm, for example 3 nm or 2-3 nm. Once the Ru metal nuclei 112a reach a critical size, only partial removal of the Ru metal nuclei 112a is readily achieved during the gas phase etching step. The partial removal is due to formation of non-volatile ruthenium oxide species (including RuO₂₍ₛ₎) on the dielectric layer 104 during the gas phase etching step. This stops or significantly slows down the removal of the remainder of the Ru metal nuclei 112.

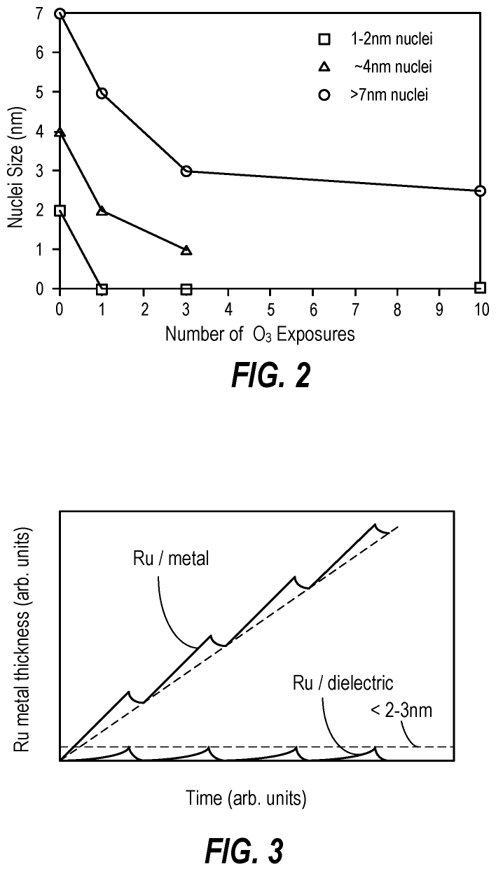

FIG. 2 shows Ru metal nuclei size as a function of number of ozone gas exposures during gas phase etching according to an embodiment of the invention. The Ru metal nuclei size is plotted for three different sizes of deposited Ru metal nuclei: 1-2 nm nuclei, ˜4 nm nuclei, and >7 nm nuclei. The gas phase etching results show that the 1-2 nm nuclei were efficiently removed after one ozone gas exposure, but etching of the >7 nm nuclei asymptotically leveled off after removal of about half of the size of the nuclei. This shows that the >7 nm nuclei were only partially etched and gradually formed etch resistant ruthenium oxide species that stopped further removal of the nuclei. It was observed that smaller nuclei (<4 nm) were found to etch about 50× faster than a continuous Ru metal film.

FIG. 3 shows thickness of Ru metal deposited on a metal layer and on a dielectric layer as a function of processing time according to an embodiment of the invention. The sequential steps of depositing Ru metal and gas phase etching using O₃ gas are repeated in order to increase a thickness of the Ru metal layer on the metal layer, while removing any Ru metal nuclei from the dielectric layer during the gas phase etching. According to one embodiment, the method further includes exposing the patterned substrate 1 to a reducing gas containing H₂ gas that converts any non-volatile ruthenium oxide species that may be formed during the O₃ gas exposure back to metallic Ru. The addition of this step provides a method for efficiently removing large Ru metal nuclei (e.g., about 4 nm and larger) that are oxidized by the O₃ gas exposure but not fully removed during the O₃ gas exposure. In one example, the O₃ gas exposure and the reducing gas exposure may be sequentially carried out at least once until the Ru metal nuclei are fully removed. According to one embodiment, the steps of gas phase etching using an O₃ gas exposure and the exposing to the reducing gas containing H₂ gas can have at least partial temporal overlap.

Following the H₂ gas exposure, the sequential steps of depositing the Ru metal and removing the Ru metal nuclei 112a may be repeated at least once.

The sequential steps of depositing the Ru metal and removing the Ru metal nuclei 112a may be repeated at least once to increase a thickness of the Ru metal layer 112 on the metal layer 106 in the recessed feature 101, until a desired thickness of the Ru metal layer 112 is achieved. In one example, shown in FIG. 1D, the sequential steps may be repeated until the via 105 is fully filled with the Ru metal layer 112.

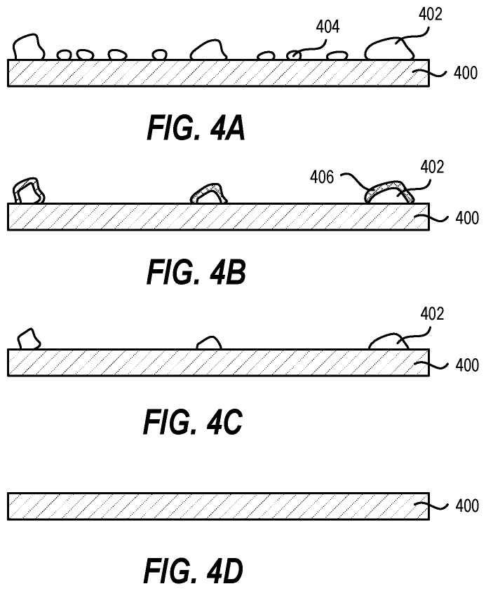

FIGS. 4A-4D schematically show etching of Ru metal nuclei using sequential O₃ gas and H₂ gas exposures according to an embodiment of the invention. FIG. 4A shows Ru metal nuclei 402 and 404 on a substrate 400, where the Ru metal nuclei 402 are larger than the Ru metal nuclei 404. FIG. 4B shows the substrate 400 following gas phase etching using O₃ gas, where the smaller Ru metal nuclei 404 have been fully removed but non-volatile ruthenium oxide species 406 have been formed on the larger Ru metal nuclei 402. FIG. 4C shows the substrate 400 following an exposure to a reducing gas containing H₂, where the non-volatile ruthenium oxide species 406 have been converted to metallic Ru, which can be further removed upon additional O₃ exposure. FIG. 4D shows the substrate 400 following additional gas phase etching using O₃ gas that fully removes the remaining Ru metal nuclei 402.

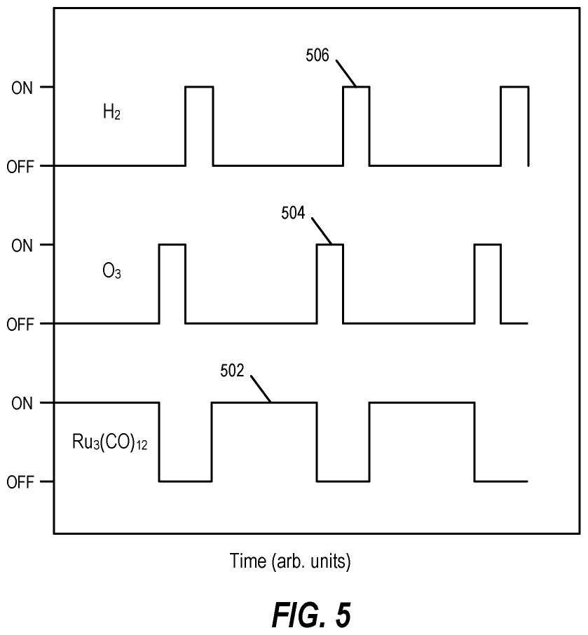

FIG. 5 shows a gas flow diagram for selectively forming a Ru metal layer on a metal layer. The gas flow diagram shows sequential exposures of Ru₃(CO)₁₂ in trace 502, O₃ in trace 504, and H₂ in trace 506. The sequential exposures are repeated until the Ru metal layer has as desired thickness.

Methods for removal of stray ruthenium metal nuclei from non-growth surfaces for selective ruthenium metal layer formation been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a semiconductor device, the method comprising:
providing a patterned substrate containing a dielectric layer and a metal layer;
depositing ruthenium (Ru) metal on the patterned substrate by vapor phase deposition, wherein a Ru metal layer is deposited on a surface of the metal layer and Ru metal nuclei are deposited on a surface of the dielectric layer;
removing the Ru metal nuclei by gas phase etching using an ozone (O₃) gas exposure that forms volatile ruthenium oxide species by oxidation of the Ru metal nuclei; and
repeating the depositing and removing steps at least once to increase a thickness of the Ru metal layer, wherein the depositing is interrupted before the Ru metal nuclei reach a critical size that results in formation of non-volatile ruthenium oxide species and incomplete removal of the Ru metal nuclei during the gas phase etching.

2. The method of claim 1, wherein the depositing and removing are performed at substantially the same substrate temperature.

3. The method of claim 1, wherein the depositing and removing are performed in a single process chamber.

4. The method of claim 1, wherein the patterned substrate is not exposed to air between the depositing and removing steps.

5. The method of claim 1, wherein the dielectric layer has a recessed feature and the metal layer is exposed in the recessed feature.

6. The method of claim 1, wherein dielectric layer contains a recessed feature that includes a trench having a first width, and a via containing the metal layer and having a second width that is less than the first width.

7. The method of claim 6, wherein the Ru metal layer fully fills the via.

8. The method of claim 1, wherein the Ru metal is deposited using a Ru₃(CO)₁₂ precursor in a CO carrier gas.

9. The method of claim 1, wherein the metal layer contains Cu metal, Ru metal, Co metal, or W metal.

10. The method of claim 1, wherein the critical size of the Ru metal nuclei is less than about 4 nm.

11. A method of forming a semiconductor device, the method comprising:
providing a patterned substrate containing a dielectric layer and a metal layer;
depositing ruthenium (Ru) metal on the patterned substrate by vapor phase deposition, wherein a Ru metal layer is deposited on a surface of the metal layer and Ru metal nuclei are deposited on a surface of the dielectric layer;
removing a portion of the Ru metal nuclei by gas phase etching using an ozone (O₃) gas exposure that forms volatile ruthenium oxide species by oxidation of the Ru metal nuclei;
exposing the patterned substrate to a reducing gas containing H₂ gas that converts non-volatile ruthenium oxide species formed during the O₃ gas exposure to metallic Ru; and
repeating the depositing, removing, and exposing steps at least once to increase a thickness of the Ru metal layer.

12. The method of claim 11, wherein the depositing and removing are performed at substantially the same substrate temperature.

13. The method of claim 11, wherein the depositing and removing are performed in the same process chamber.

14. The method of claim 11, wherein the removing and exposing steps are repeated at least once to fully remove the Ru metal nuclei before the depositing step is repeated.

15. The method of claim 11, wherein the steps of gas phase etching using an O₃ gas exposure and the exposing the patterned substrate to the reducing gas containing H₂ gas have at least partial temporal overlap.

16. The method of claim 11, wherein the dielectric layer has a recessed feature and the metal layer is exposed in the recessed feature.

17. The method of claim 11, wherein dielectric layer contains a recessed feature that includes a trench having a first width, and a via containing the metal layer and having a second width that is less than the first width.

18. The method of claim 17, wherein the Ru metal layer fully fills the via.

19. The method of claim 11, wherein the Ru metal is deposited using a Ru₃(CO)₁₂ precursor in a CO carrier gas.

20. The method of claim 11, wherein the metal layer contains Cu metal, Ru metal, Co metal, or W metal.
